(19) United States
(12) Patent Application Publication
(10) Pub. No.: US 2025/0081483 A1
(43) Pub. Date: Mar. 6, 2025

(54) INTEGRATED CIRCUIT DEVICE

(71) Applicant: Samsung Electronics Co., Ltd., Suwon-si (KR)

(72) Inventors: Yeseul LEE, Suwon-si (KR); Jongyeong MIN, Suwon-si (KR); Kyooho JUNG, Suwon-si (KR); Joonsuk PARK, Suwon-si (KR); Jiye BAEK, Suwon-si (KR); Jinwook LEE, Suwon-si (KR)

(73) Assignee: Samsung Electronics Co., Ltd., Suwon-si (KR)

(21) Appl. No.: 18/636,601

(22) Filed: Apr. 16, 2024

(30) Foreign Application Priority Data
Sep. 1, 2023 (KR) 10-2023-0116267

(51) Int. Cl. H10B 12/00

(52) U.S. Cl. CPC H10D 1/716; H10B 12/31

(57) ABSTRACT

An integrated circuit device includes a lower electrode, a dielectric film covering the lower electrode, an upper electrode covering the dielectric film, and a multilayered interface structure between the dielectric film and the upper electrode, wherein the multilayered interface structure includes a transition metal-aluminum (Al) complex oxide layer including a transition metal oxide layer in which Al atoms are dispersed, the transition metal-Al complex oxide layer being in contact with the dielectric film, and an upper interface layer including a metal oxide or a metal oxynitride, the upper interface layer being in contact with the transition metal-Al complex oxide layer.

### CROSS-REFERENCE TO RELATED APPLICATION

This application is based on and claims priority under 35 U.S.C. § 119 to Korean Patent Application No. 10-2023-0116267, filed on Sep. 1, 2023, in the Korean Intellectual Property Office, the disclosure of which is incorporated by reference herein in its entirety.

### BACKGROUND

The inventive concepts relate to integrated circuit (IC) devices, and more particularly, to IC devices including a capacitor.

With the downscaling of IC devices, spaces occupied by capacitors have rapidly been reduced. Accordingly, there is a need to develop a structure that may overcome spatial limitations and design rule limitations in capacitors and improve capacitances of the capacitors to maintain desired electrical characteristics.

### SUMMARY

The inventive concepts provide integrated circuit (IC) devices, which may have a structure capable of maintaining desired electrical characteristics by providing a capacitor having a relatively high capacitance.

According to an aspect of the inventive concepts, there is provided an IC device including a lower electrode, a dielectric film covering the lower electrode, an upper electrode covering the dielectric film, and a multilayered interface structure between the dielectric film and the upper electrode, wherein the multilayered interface structure includes a transition metal-aluminum (Al) complex oxide layer including a transition metal oxide layer in which Al atoms are dispersed, the transition metal-Al complex oxide layer being in contact with the dielectric film, and an upper interface layer including a metal oxide or a metal oxynitride, the upper interface layer being in contact with the transition metal-Al complex oxide layer.

According to another aspect of the inventive concepts, there is provided an IC device including a substrate including an active region, a conductive region formed on the active region, a capacitor formed on the conductive region, wherein the capacitor includes a lower electrode in contact with the conductive region, a dielectric film covering the lower electrode, an upper electrode covering the dielectric film, and a multilayered interface structure between the dielectric film and the upper electrode, wherein the multilayered interface structure includes a transition metal-Al complex oxide layer including a transition metal oxide layer in which Al atoms are dispersed, the transition metal-Al complex oxide layer being in contact with the dielectric film, and an upper interface layer including a metal oxide or a metal oxynitride, the upper interface layer being in contact with the transition metal-Al complex oxide layer.

According to another aspect of the inventive concepts, there is provided an IC device including a substrate including an active region, a plurality of conductive regions formed on the active region, an insulating pattern extending in a lateral direction on the plurality of conductive regions, the insulating pattern having a plurality of openings vertically overlapping the plurality of conductive regions, a plurality of lower electrodes passing through the insulating pattern via the plurality of openings and extending long in a vertical direction, the plurality of lower electrodes being connected to the plurality of conductive regions, an insulating support pattern extending in the lateral direction spaced apart from the insulating pattern in the vertical direction, the insulating support pattern being in contact with a partial region of each of the plurality of lower electrodes to support the plurality of lower electrodes, a dielectric film covering the plurality of lower electrodes, the insulating pattern, and the insulating support pattern, an upper electrode covering the dielectric film, a lower interface layer between the plurality of lower electrodes and the dielectric film, the lower interface layer being in contact with the dielectric film, and a multilayered interface structure between the dielectric film and the upper electrode, wherein the lower interface layer includes a Ti oxide film doped with a pentavalent dopant metal, wherein the multilayered interface structure includes a transition metal-Al complex oxide layer including a transition metal oxide layer in which Al atoms are dispersed, the transition metal-Al complex oxide layer being in contact with the dielectric film, and an upper interface layer including a metal oxide or a metal oxynitride, the upper interface layer being in contact with the transition metal-Al complex oxide layer.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view of main components of an integrated circuit (IC) device according to some example embodiments;

FIG. 2A is a cross-sectional view of a multilayered interface structure, which may be used for an IC device according to some example embodiments;

FIG. 2B is a cross-sectional view of a multilayered interface structure, which may be used for an IC device according to some example embodiments

FIG. 3 illustrates a schematic plan layout of some components of a memory cell array region of an IC device, according to some example embodiments;

FIG. 4A is a plan view of some components of a memory cell region of an IC device according to some example embodiments;

FIG. 4B is a schematic cross-sectional view of some components corresponding to a cross-section taken along line 2X-2X′ of FIG. 4A;

FIG. 4C is an enlarged cross-sectional view of region “EX1” of FIG. 4B;

FIGS. 5A to 5J are cross-sectional views of a process sequence of a method of manufacturing an IC device, according to some example embodiments;

FIG. 6A is a graph of X-ray diffraction (XRD) measurement results showing a comparison of a degree of crystallization of a dielectric film included in a capacitor of an IC device according to some example embodiments and a Comparative Example;

FIG. 6B is a graph of measurement results showing a comparison of a capacitance of a capacitor of an IC device according to some example embodiments and a Comparative Example; and

FIGS. 7A, 7B, and 7C are graphs of XRD measurement results showing a comparison of degrees of crystallization of dielectrics films included in capacitors of IC devices according to some example embodiments and Comparative Example.

### DETAILED DESCRIPTION

Hereinafter, some example embodiments will be described in detail with reference to the accompanying drawings. The same reference numerals are used to denote the same elements in the drawings, and repeated descriptions thereof will be omitted.

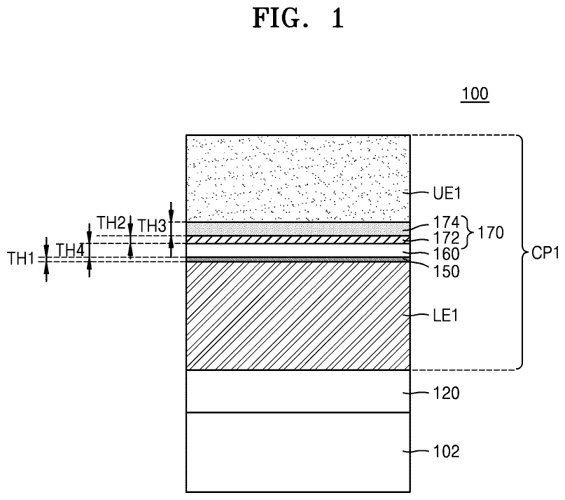

FIG. 1 is a cross-sectional view of main components of an integrated circuit (IC) device 100 according to some example embodiments.

Referring to FIG. 1, the IC device 100 may include a substrate 102, a lower structure 120 formed on the substrate 102, and a capacitor CP1 formed on the lower structure 120.

The substrate 102 may include a semiconductor element, such as silicon (Si) and/or germanium (Ge), or a compound semiconductor, such as silicon carbide (SiC), gallium arsenide (GaAs), indium arsenide (InAs), and/or indium phosphide (InP). The substrate 102 may include a semiconductor substrate and structures including at least one insulating film and/or at least one conductive region, which are formed on the semiconductor substrate. The at least one conductive region may include, for example, a doped well or a doped structure. In some example embodiments, the substrate 102 may include various device isolation structures, such as shallow trench isolation (STI) structures.

In some example embodiments, the lower structure 120 may include an insulating film. In other example embodiments, the lower structure 120 may include various conductive regions, for example, wiring layers, contact plugs, and transistors, and insulating films configured to electrically insulate the conductive regions from each other.

The capacitor CP1 may include a lower electrode LE1, a dielectric film 160 covering the lower electrode LE1, an upper electrode UE1 covering the dielectric film 160, and a multilayered interface structure 170 between the dielectric film 160 and the upper electrode UE1. The multilayered interface structure 170 may include a transition metal-aluminum (Al) complex oxide layer 172 and an upper interface layer 174, which are sequentially stacked from the dielectric film 160 toward the upper electrode UE1.

In the multilayered interface structure 170, the transition metal-Al complex oxide layer 172 may include a transition metal oxide layer in which Al atoms are dispersed. The upper interface layer 174 may include a metal oxide or a metal oxynitride.

In some example embodiments, the transition metal-Al complex oxide layer 172 may include a first metal, which is a transition metal, and the upper interface layer 174 may include a second metal of a different type from the first metal. The second metal may be a transition metal or a post-transition metal. In some example embodiments, the first metal included in the transition metal-Al complex oxide layer 172 may be selected from zirconium (Zr) and/or hafnium (Hf), and the second metal included in the upper interface layer 174 may be selected from titanium (Ti), niobium (Nb), tantalum (Ta), antimony (Sn), and/or molybdenum (Mo).

In some example embodiments, the transition metal-Al complex oxide layer 172 may include zirconium oxide in which Al atoms are irregularly dispersed or hafnium oxide in which Al atoms are irregularly dispersed. In some example embodiments, in the transition metal-Al complex oxide layer 172, a content ratio of Al atoms may be in a range of at least 1 atom % (at %) and less than 40 at %, for example, a range of about 1 at % to about 30 at %, without being limited thereto.

In some example embodiments, the upper interface layer 174 may include an oxide of at least one metal selected from Ti, Nb, Ta, Sn, and/or Mo or an oxynitride of at least one metal selected from Ti, Nb, Ta, Sn, and Mo. For example, the upper interface layer 174 may include a Ti oxide, a Ti oxynitride, a Nb oxide, a Nb oxynitride, a Ta oxide, a Ta oxynitride, a Sn oxide, a Sn oxynitride, a Mo oxide, a Mo oxynitride, or a combination thereof.

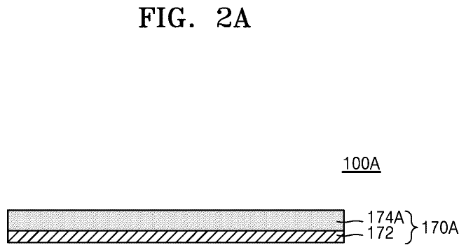

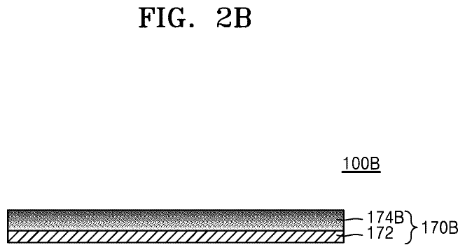

FIG. 2A is a cross-sectional view of a multilayered interface structure 170A according to some example embodiments, which may be used as the multilayered interface structure 170 shown in FIG. 1.

Referring to FIG. 2A, the multilayered interface structure 170A may include an upper interface layer 174A including components that are substantially uniformly dispersed. More specifically, when the upper interface layer 174A includes a metal oxide, metal atoms and oxygen atoms included in the upper interface layer 174A may be substantially uniformly dispersed regardless of position inside the upper interface layer 174A. For example, when the upper interface layer 174A includes a Ti oxide, Ti atoms and oxygen atoms may be substantially uniformly dispersed regardless of position inside the upper interface layer 174A.

When the upper interface layer 174A includes a metal oxynitride, metal atoms, oxygen atoms, and nitrogen atoms included in the upper interface layer 174A may be substantially uniformly dispersed regardless of position inside the upper interface layer 174A. For example, when the upper interface layer 174A includes a Mo oxynitride, the Mo atoms, oxygen atoms, and nitrogen atoms may be substantially uniformly dispersed regardless of position inside the upper interface layer 174A. In the upper interface layer 174A, a content ratio of nitrogen atoms may be in a range of about 10 at % to about 30 at % and a content ratio of oxygen atoms may be in a range of about 10 at % to about 30 at %. For example, a content ratio of the nitrogen atoms in a range of about 10 at % to about 30 at % may refer to a content of nitrogen atoms in the upper interface layer 174A in a range of about 10 at % to about 30 at %. For example, a content ratio of the oxygen atoms in a range of about 10 at % to about 30 at % may refer to a content of nitrogen atoms in the upper interface layer 174A in a range of about 10 at % to about 30 at %.

FIG. 2B is a cross-sectional view of a multilayered interface structure 170B according to some example embodiment, which may be used as the multilayered interface structure 170 shown in FIG. 1.

Referring to FIG. 2B, the multilayered interface structure 170B may include an upper interface layer 174B including components that are non-uniformly dispersed according to position. More specifically, the upper interface layer 174B may include a metal oxynitride. In the upper interface layer 174B, a content ratio of nitrogen atoms may increase toward the transition metal-Al complex oxide layer 172, and a content ratio of oxygen atoms may increase toward the upper electrode (refer to UE1 in FIG. 1). In the upper interface layer 174B, metal atoms may be substantially uniformly dispersed regardless of position. In the upper interface layer 174B, a content ratio of nitrogen atoms and a content ratio of oxygen atoms may be in a range of about 10 at % to about 30 at %.

For example, when the upper interface layer 174B includes a Mo oxynitride layer, a content ratio of nitrogen atoms in the Mo oxynitride layer may increase toward the transition metal-Al complex oxide layer 172, and a content ratio of oxygen atoms in the Mo oxynitride layer may increase toward the upper electrode (refer to UE1 in FIG. 1). When the upper interface layer 174B includes a Mo oxynitride layer, the upper interface layer 174B may induce the dielectric film 160 including a Hf oxide film (e.g., a HfO₂ film) to have a crystal structure of a tetragonal phase or an orthorhombic phase. When the HfO₂ film has a crystal structure of a tetragonal phase or a crystal structure of an orthorhombic phase, a dielectric constant of the dielectric film 160 may be higher than when the HfO₂ film has a crystal structure of a monoclinic phase. Therefore, because the capacitor CP1 includes the upper interface layer 174B including a Mo oxynitride layer, a capacitance of the capacitor CP1 may further improve without increasing a leakage current in the capacitor CP1.

Referring back to FIG. 1, the transition metal-Al complex oxide layer 172 may have one surface in contact, for example direct contact, with the dielectric film 160. Another surface of the transition metal-Al complex oxide layer 172, which is opposite to the one surface of the transition metal-Al complex oxide layer 172, may be in contact, for example direct contact, with the upper interface layer 174. The upper interface layer 174 may have one surface in contact, for example direct contact, with the transition metal-Al complex oxide layer 172. Another surface of the upper interface layer 174, which is opposite to the one surface of the upper interface layer 174, may be in contact, for example direct contact, with the upper electrode UE1.

As shown in FIG. 1 the capacitor CP1 may further include a lower interface layer 150 between the lower electrode LE1 and the dielectric film 160. One surface of a lower interface layer 150 may be in contact, for example direct contact, with the lower electrode LE1, and another surface of the lower interface layer 150, which is opposite to the one surface of the lower interface layer 150, may be in contact, for example direct contact, with the dielectric film 160.

The lower interface layer 150 may include a Ti oxide film doped with a dopant metal that is pentavalent. In some example embodiments, the dopant metal may include niobium (Nb), tantalum (Ta), antimony (Sb), vanadium (V), and/or a combination thereof.

In the lower interface layer 150, Ti may be tetravalent, and the dopant metal may be pentavalent, and thus, the lower interface layer 150 including the Ti oxide film doped with the dopant metal may include excess electrons. Accordingly, the electrical conductivity of the lower interface layer 150 may improve, and thus, the capacitance of the capacitor CP1 may improve.

In the lower interface layer 150, a content ratio of the dopant metal may be in a range of about 1 at % to about 10 at %. For example, in the lower interface layer 150, a content ratio of the dopant metal may be in a range of about 1 at % to about 4 at %. When a content ratio of the dopant metal is excessively low in the lower interface layer 150, it may be difficult to ensure conductivity. When the content ratio of the dopant metal is excessively high in the lower interface layer 150, electrical characteristics required by the capacitor CP1 may be adversely affected.

In some example embodiments, the lower interface layer 150 may include a Ti oxide film doped with one type of dopant metal. For example, the lower interface layer 150 may include a Nb-doped Ti oxide film. In the Nb-doped Ti oxide film, a content ratio of Nb atoms may be in a range of about 1 at % to about 4 at %.

In other example embodiments, the lower interface layer 150 may include a Ti oxide film doped with dopant metals of a plurality of types. The dopant metals of a plurality of types may include first dopant atoms including Nb and second dopant atoms including at least one selected from Ta, Sb, and/or V. In the lower interface layer 150, a content ratio of the sum of the first dopant atoms and the second dopant atoms may be in a range of about 1 at % to about 4 at %.

A thickness TH1 of the lower interface layer 150 may be less than a thickness of the dielectric film 160. In some example embodiments, the thickness TH1 of the lower interface layer 150 may be in a range of about 0.1 Å to about 10 Å, without being limited thereto.

A thickness TH2 of the transition metal-Al complex oxide layer 172 may be in a range of about 1 Å to about 30 Å, without being limited thereto. A thickness TH3 of the upper interface layer 174 may be in a range of about 1 Å to about 100 Å, without being limited thereto. In some example embodiments, the thickness TH1 of the lower interface layer 150 may be less than the thickness TH2 of the transition metal-Al complex oxide layer 172 and the thickness TH3 of the upper interface layer 174.

The dielectric film 160 may include a high-k dielectric film. As used herein, the term “high-k dielectric film” refers to a dielectric film having a higher dielectric constant than a silicon oxide film. In some example embodiments, the dielectric film 160 may include a metal oxide including at least one metal selected from hafnium (Hf), zirconium (Zr), aluminum (Al), niobium (Nb), cerium (Ce), lanthanum (La), tantalum (Ta), and/or titanium (Ti). In some example embodiments, the dielectric film 160 may have a single film structure including one high-k dielectric film. In other example embodiments, the dielectric film 160 may have a multilayered structure including a plurality of high-k dielectric films that are sequentially stacked on the lower electrode LE1. The high-k dielectric film may include a HfO₂ film, a ZrO₂ film, an Al₂O₃ film, a La₂O₃ film, a Ta₂O₃ film, a Nb₂O₅ film, a CeO₂ film, a TiO₂ film, a GeO₂ film, or a combination thereof, without being limited thereto. In some example embodiments, a thickness TH4 of the dielectric film 160 may be in a range of about 20 Å to about 80 Å, without being limited thereto.

A surface of the dielectric film 160, which faces the upper electrode UE1, may be in contact, for example direct contact, with the transition metal-Al complex oxide layer 172 of the multilayered interface structure 170, and the multilayered interface structure 170 including the transition metal-Al complex oxide layer 172 and the upper interface layer 174 may increase a degree of crystallization of the dielectric film 160. Accordingly, even when a thickness of the dielectric film 160 is reduced by reducing a space occupied by the capacitor CP1 with the downscaling of the IC device 100, the dielectric film 160 may be sufficiently crystallized by the multilayered interface structure 170. The dielectric film 160 may have a crystal structure of a tetragonal phase, an orthorhombic phase, or a monoclinic phase.

In some example embodiments, the transition metal-Al complex oxide layer 172 may include a first metal, which is a transition metal, the upper interface layer 174 may include a second metal of a different type from the first metal, and the dielectric film 160 may include an oxide of the first metal. For example, the transition metal-Al complex oxide layer 172 may include the first metal selected from Zr and Hf, the upper interface layer 174 may include the second metal selected from Ti, Nb, Ta, Sn, and/or Mo, and the dielectric film 160 may include an oxide of the first metal selected from Zr and/or Hf.

The upper electrode UE1 may face the lower electrode LE1 with the lower interface layer 150, the dielectric film 160, and the multilayered interface structure 170 therebetween. In some example embodiments, the lower electrode LE1 and the upper electrode UE1 may include the same metals as each other. For example, each of the lower electrode LE1 and the upper electrode UE1 may include titanium nitride (TiN). In other example embodiments, the lower electrode LE1 and the upper electrode UE1 may include different metals from each other.

Each of the lower electrode LE1 and the upper electrode UE1 may include a metal film, a conductive metal oxide film, a conductive metal nitride film, a conductive metal oxynitride film, or a combination thereof. In some example embodiments, each of the lower electrode LE1 and the upper electrode UE1 may include niobium (Nb), Nb oxide, Nb nitride, Nb oxynitride, titanium (Ti), Ti oxide, Ti nitride, Ti oxynitride, cobalt (Co), Co oxide, Co nitride, Co oxynitride, tin (Sn), Sn oxide, Sn nitride, Sn oxynitride, and/or a combination thereof. For example, each of the lower electrode LE1 and the upper electrode UE1 may include TiN, NbN, CON, SnO₂, and/or a combination thereof. In other example embodiments, each of the lower electrode LE1 and the upper electrode UE1 may include TaN, TiAlN, TaAlN, V, VN, Mo, MON, W, WN, Ru, RuO₂, SrRuO₃, Ir, IrO₂, Pt, PtO, SRO(SrRuO₃), BSRO((Ba, Sr) RuO₃), CRO(CaRuO₃), LSCO((La,Sr) CoO₃), and/or a combination thereof. However, a constituent material of each of the lower electrode LE1 and the upper electrode UE1 is not limited thereto.

In the IC devices 100, 100A, and 100B described with reference to FIGS. 1, 2A, and 2B, the capacitor CP1 may include the multilayered interface structure 170, 170A, or 170B between the dielectric film 160 and the upper electrode UE1, and the multilayered interface structure 170, 170A, or 170B may include the transition metal-Al complex oxide layer 172 and the upper interface layer 174, 174A, or 174B including a metal oxide or a metal oxynitride, which are sequentially stacked from the dielectric film 160 toward the upper electrode UE1. Even when a thickness of the dielectric film 160 is reduced by reducing a space occupied by the capacitor CP1 with the downscaling of the IC device 100, a degree of crystallization of the dielectric film 160 may be improved by the multilayered interface structure 170. Furthermore, the capacitor CP1 of the IC device 100 may further include the lower interface layer 150, which is between the lower electrode LE1 and the dielectric film 160 and in contact with the dielectric film 160, and thus, a degree of crystallization of the dielectric film 160 may further improve. Therefore, the capacitance of the capacitor CP1 including the dielectric film 160 may increase, and the reliability of the IC device 100 may improve.

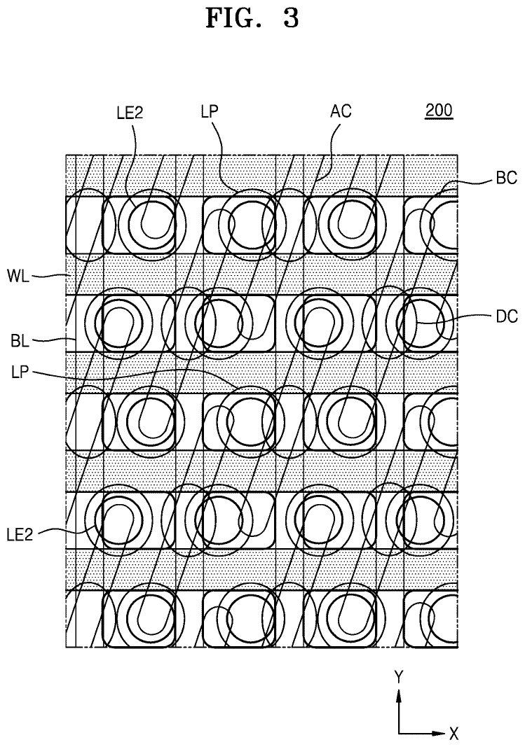

FIG. 3 illustrates a schematic plan layout of some components of a memory cell array region of an IC device 200, according to some example embodiments.

Referring to FIG. 3, the IC device 200 may include a plurality of active regions AC, which extend in a lateral direction at an angle to an X direction and a Y direction on a plane. A plurality of word lines WL may intersect with the plurality of active regions AC and extend parallel to each other in the X direction. A plurality of bit lines BL may be on the plurality of word lines WL and extend parallel to each other in the Y direction, which intersects with the X direction. Each of the plurality of bit lines BL may be connected to the active region AC through a direct contact DC.

A plurality of buried contacts BC may be formed between two adjacent ones of the plurality of bit lines BL. A plurality of conductive landing pads LP may be formed on the plurality of buried contacts BC. At least a portion of each of the plurality of conductive landing pads LP may overlap a buried contact BC. A plurality of lower electrodes LE2 may be formed on the plurality of conductive landing pads LP and be apart from each other. The plurality of lower electrode LE2 may be connected to the plurality of active regions AC through the plurality of buried contacts BC and the plurality of conductive landing pads LP.

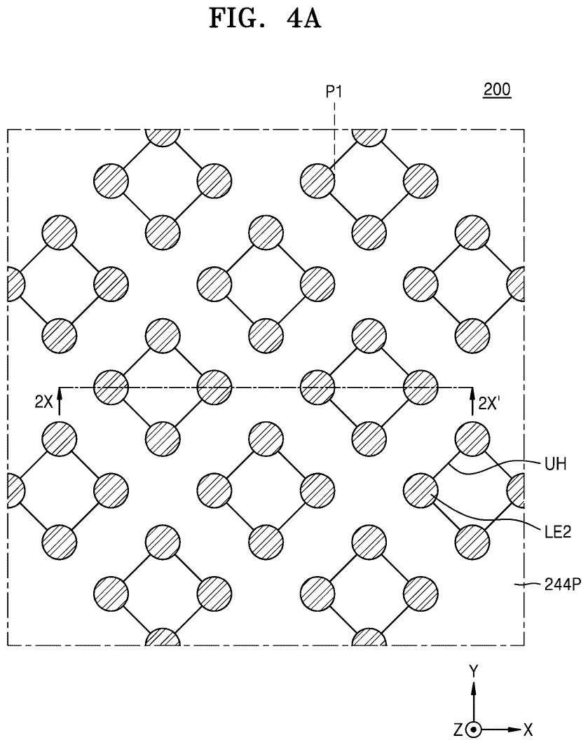

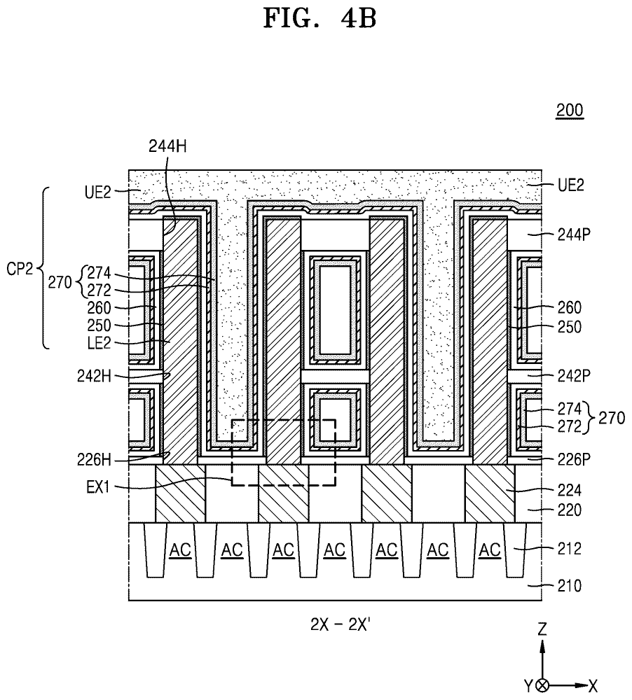

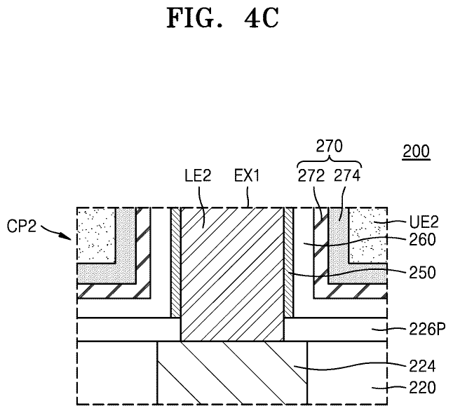

FIG. 4A is a plan view of some components of the IC device 200 shown in FIG. 3. FIG. 4B is a schematic cross-sectional view of some components corresponding to a cross-section taken along line 2X-2X′ of FIG. 4A. FIG. 4C is an enlarged cross-sectional view of region “EX1” of FIG. 4B.

Referring to FIGS. 4A to 4C, the IC device 200 may include a substrate 210 including a plurality of active regions AC and a lower structure 220 formed on the substrate 210. A plurality of conductive regions 224 may pass through the lower structure 220 and be connected to the plurality of active regions AC.

The substrate 210 may include a semiconductor element, such as Si and/or Ge, or a compound semiconductor, such as SiC, GaAs, InAs, and/or InP. The substrate 210 may include a semiconductor substrate and structures including at least one insulating film or at least one conductive region, which are formed on the semiconductor substrate. The at least one conductive region may include, for example, a doped well or a doped structure. A device isolation film 212 defining the plurality of active regions AC may be formed in the substrate 210. The device isolation film 212 may include an oxide film, a nitride film, or a combination thereof.

In some embodiments, the lower structure 220 may include an insulating film, which includes a silicon oxide film, a silicon nitride film, or a combination thereof. In other example embodiments, the lower structure 220 may include various conductive regions, for example, wiring layers, contact plugs, and transistors, and insulating films configured to electrically insulate the conductive regions from each other. The plurality of conductive regions 224 may include polysilicon, a metal, a conductive metal nitride, a metal silicide, or a combination thereof. The lower structure 220 may include the plurality of bit lines BL described with reference to FIG. 3. Each of the plurality of conductive regions 224 may include a buried contact BC and a conductive landing pad LP, which are described with reference to FIG. 3.

An insulating pattern 226P having a plurality of openings 226H may be on the lower structure 220 and the plurality of conductive regions 224. The plurality of openings 226H may be in positions overlapping the plurality of conductive regions 224 in a vertical direction (Z direction). The insulating pattern 226P may include a silicon nitride (SiN) film, a silicon carbon nitride (SiCN) film, a silicon boron nitride (SiBN) film, or a combination thereof. As used herein, each of the terms “SiN,” “SiCN,” and “SiBN” refers to a material including elements included therein, without referring to a chemical formula representing a stoichiometric relationship.

A plurality of capacitors CP2 may be on the plurality of conductive regions 224. Each of the plurality of capacitors CP2 may include a lower electrode LE2, a dielectric film 260 covering the lower electrode LE2, and an upper electrode UE2 covering the dielectric film 260, and a multilayered interface structure 270 between the dielectric film 260 and the upper electrode UE2. The multilayered interface structure 270 may include a transition metal-Al complex oxide layer 272 and an upper interface layer 274, which are sequentially stacked from the dielectric film 260 toward the upper electrode UE2. The capacitor CP2 may further include a lower interface layer 250 between the lower electrode LE2 and the dielectric film 260. Respective constituent materials of the lower electrode LE2, the lower interface layer 250, the dielectric film 260, the transition metal-Al complex oxide layer 272, the upper interface layer 274, and the upper electrode UE2 are substantially the same as those of the lower electrode LE1, the lower interface layer 150, the dielectric film 160, the transition metal-Al complex oxide layer 172, the upper interface layer 174, and the upper electrode UE1, which have been described with reference to FIGS. 1, 2A, and 2B.

The insulating pattern 226P may be adjacent to a lower end of each of a plurality of lower electrodes LE2. Each of the plurality of lower electrodes LE2 may have a pillar shape, which extends long from a top surface of the conductive region 224 through the opening 226H of the insulating pattern 226P in a direction away from the substrate 210 in the vertical direction (Z direction). Although FIG. 4B illustrates an example in which each of the plurality of lower electrodes LE2 has a pillar shape, the inventive concept is not limited thereto. For example, each of the plurality of lower electrodes LE2 may have a cup-shaped sectional structure or a cylindrical sectional structure with a blocked bottom portion.

The plurality of lower electrodes LE2 may be supported by a lower insulating support pattern 242P and an upper insulating support pattern 244P. The plurality of lower electrodes LE2 and the upper electrode UE2 may face each other with the lower interface layer 250, the dielectric film 260, the transition metal-Al complex oxide layer 272, and the upper interface layer 274 therebetween.

The lower interface layer 250 may be between the lower electrode LE2 and the dielectric film 260. The lower interface layer 250 may conformally cover an outer sidewall and an uppermost surface of the lower electrode LE2. The lower interface layer 250 may not be between the lower electrode LE2 and the insulating pattern 226P, between the lower electrode LE2 and the lower insulating support pattern 242P, and between the lower electrode LE2 and the upper insulating support pattern 244P. The lower interface layer 250 may not be between the insulating pattern 226P and the dielectric film 260, between the lower insulating support pattern 242P and the dielectric film 260, and between the upper insulating support pattern 244P and the dielectric film 260.

The dielectric film 260 may cover the lower electrode LE2, the lower insulating support pattern 242P, and the upper insulating support pattern 244P. The dielectric film 260 may include portions in contact, for example direct contact, with the insulating pattern 226P, the lower interface layer 250, the lower insulating support pattern 242P, and the upper insulating support pattern 244P, respectively. Portions of the dielectric film 260, which face the lower electrode LE2, may be apart from the lower electrode LE2 with the lower interface layer 250 therebetween. The dielectric film 260 may not include a portion in contact, for example direct contact, with the lower electrode LE2. As shown in FIG. 4B, the lower interface layer 250 may be in contact, for example direct contact, with the uppermost surface of the lower electrode LE2.

The upper insulating support pattern 244P may extend in the lateral direction (a direction parallel to the X-Y plane in FIG. 4B), which is parallel to the substrate 210, while surrounding an upper end of each of the plurality of lower electrodes LE2. A plurality of holes 244H through which the plurality of lower electrodes LE2 pass may be formed in the upper insulating support pattern 244P. An inner sidewall of each of the plurality of holes 244H formed in the upper insulating support pattern 244P may be in contact, for example direct contact, with the outer sidewall of the lower electrode LE2. A top surface of each of the plurality of lower electrodes LE2 may be on the same plane with a top surface of the upper insulating support pattern 244P, without being limited thereto.

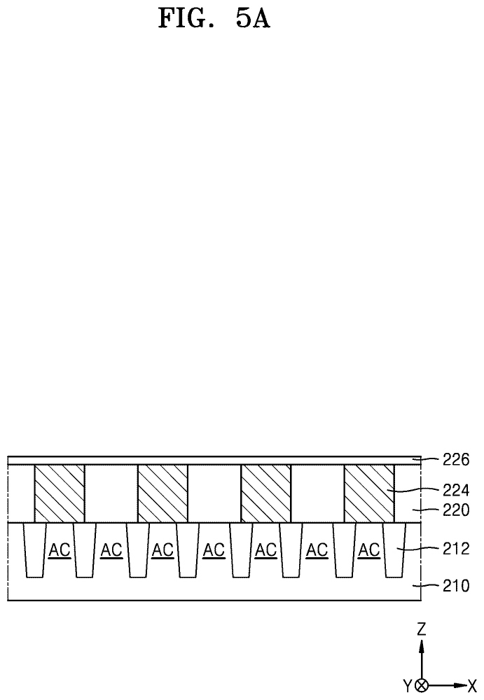

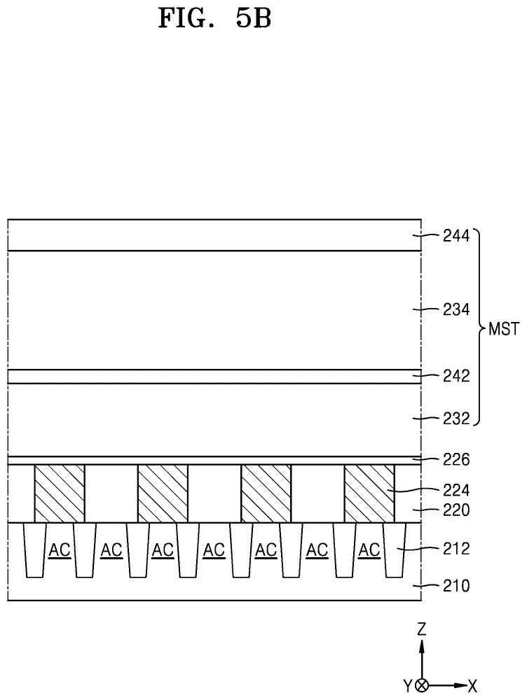

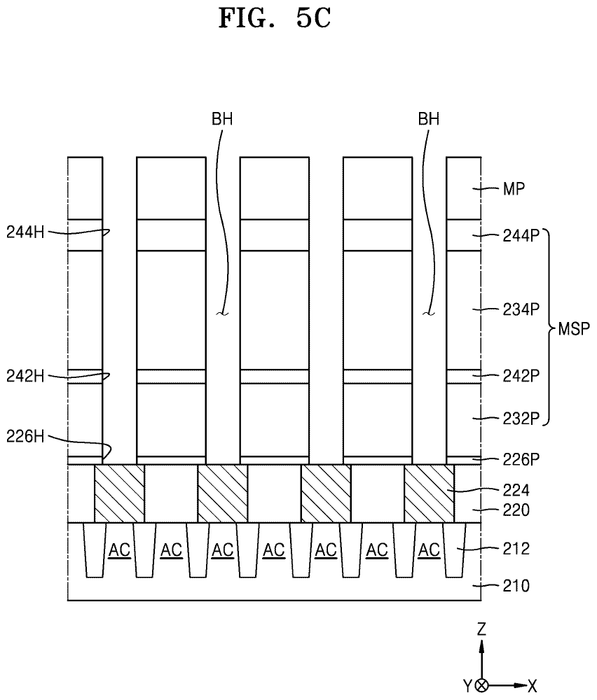

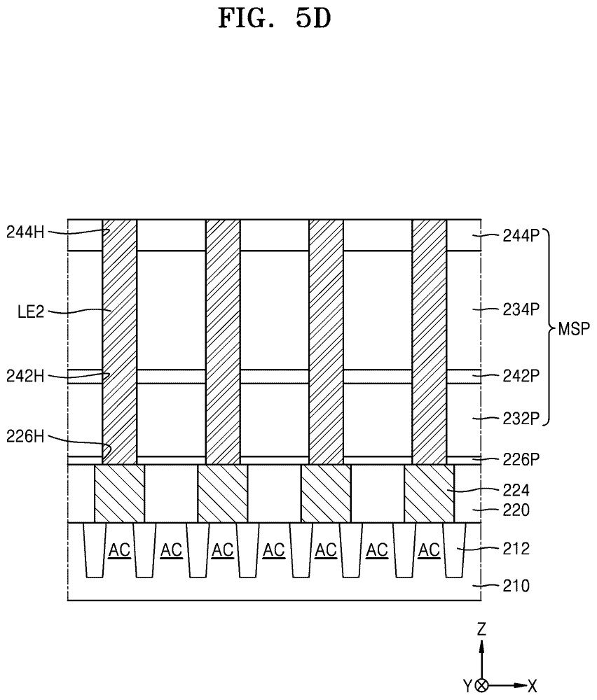

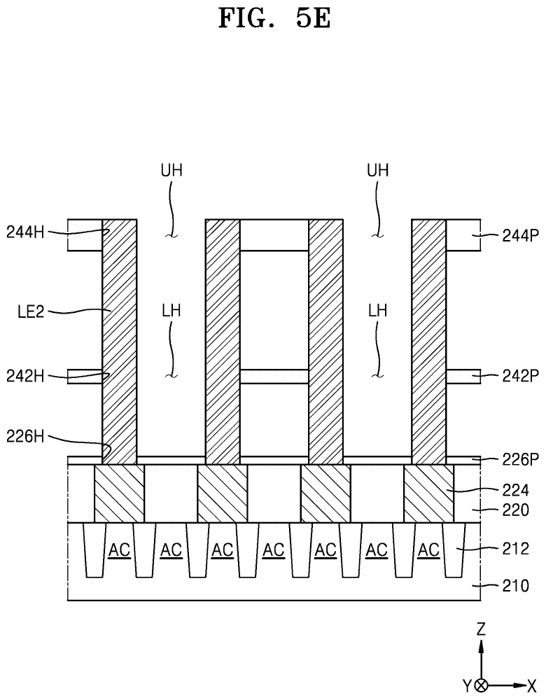

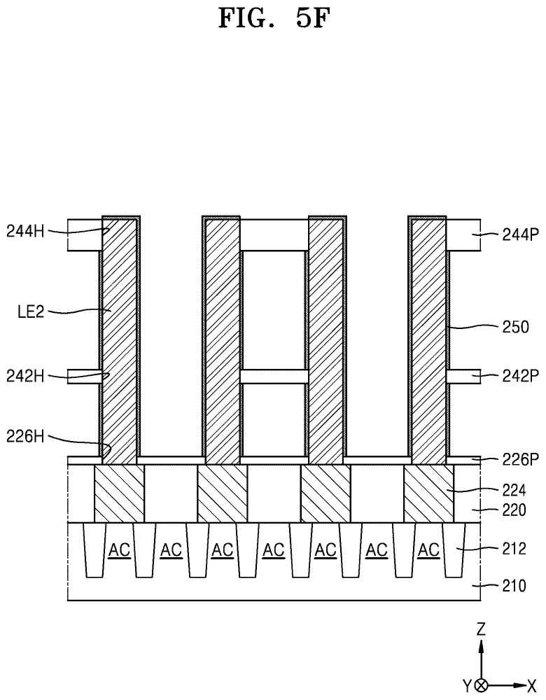

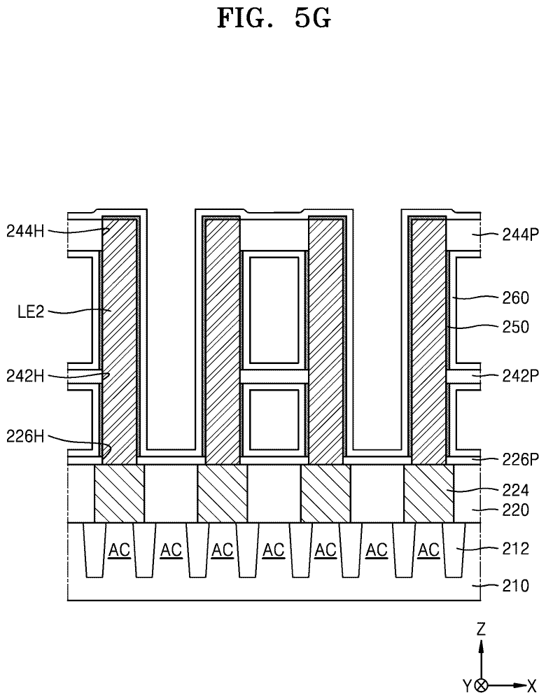

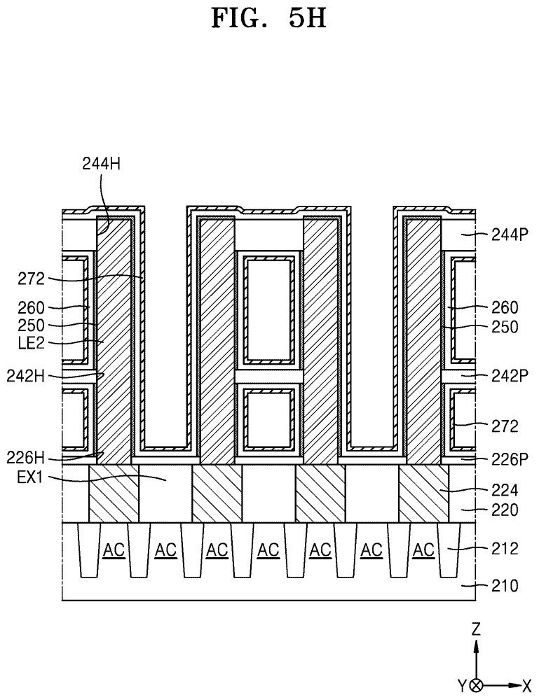

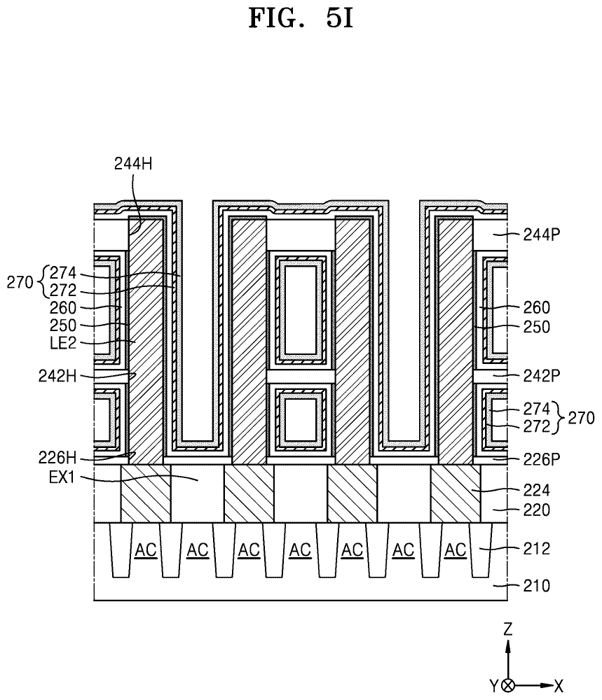

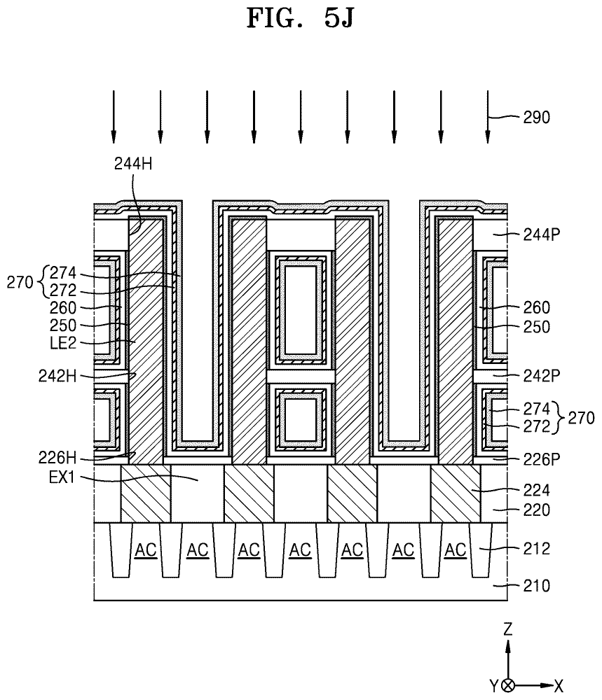

The lower insulating support pattern 242P may extend in the lateral direction (the direction parallel to the X-Y plane in FIG. 4B), which is parallel to the substrate 210, and be in contact, for example direct contact, with the outer sidewalls of the plurality of lower electrodes LE2 between the substrate 210 and the upper insulating support pattern 244P. A plurality of holes 242H, through which the plurality of lower electrodes LE2 pass, and a plurality of lower holes (refer to LH in FIG. 5E) may be formed in the lower insulating support pattern 242P. The plurality of lower electrodes LE2 may pass through the plurality of holes 244H formed in the upper insulating support pattern 244P and the plurality of holes 242H formed in the lower insulating support pattern 242P and extend in the vertical direction (Z direction).

As shown in FIG. 4A, a plurality of upper holes UH may be formed in the upper insulating support pattern 244P. FIG. 4A illustrates an example configuration in which a planar shape of each of the plurality of upper holes UH is substantially a rhombic planar shape of which vertices are respectively formed by four adjacent lower electrodes LE2. However, the planar shape of each of the plurality of upper holes UH is not limited to that shown in FIG. 4A and may be variously modified and changed within the scope of the inventive concept. The plurality of lower holes LH having a planar shape corresponding to the planar shape of the plurality of upper holes UH may be formed in the lower insulating support pattern 242P.

Each of the lower insulating support pattern 242P and the upper insulating support pattern 244P may include a silicon nitride (SiN) film, a silicon carbon nitride (SiCN) film, a silicon boron nitride film (SiBN) film, or a combination thereof. In some example embodiments, the lower insulating support pattern 242P and the upper insulating support pattern 244P may include the same materials as each other. In other example embodiments, the lower insulating support pattern 242P and the upper insulating support pattern 244P may include different materials from each other. In an example, each of the lower insulating support pattern 242P and the upper insulating support pattern 244P may include a SiCN film. In another example, the lower insulating support pattern 242P may include a SiCN film, and the upper insulating support pattern 244P may include a SiBN film. However, the inventive concept is not limited to the materials described above.

In the IC device 200 described with reference to FIGS. 3 and 4A to 4C, the capacitor CP2 may include a multilayered interface structure 270 between the dielectric film 260 and the upper electrode UE2. The multilayered interface structure 270 may include a transition metal-Al complex oxide layer 272 and an upper interface layer 274, which are sequentially stacked from the dielectric 260 toward the upper electrode UE2. The upper interface layer 274 may include a metal oxide or a metal oxynitride. Even when a thickness of the dielectric film 260 is reduced by reducing a space occupied by the capacitor CP2 with the downscaling of the IC device 200, a degree of crystallization of the dielectric film 260 may be improved by the multilayered interface structure 270. In addition, the capacitor CP2 of the IC device 200 may further include a lower interface layer 250, which is between the lower electrode LE2 and the dielectric film 260 and in contact with the dielectric film 260, and thus, a degree of crystallization of the dielectric film 260 may further improve. Therefore, the capacitance of the capacitor CP2 including the dielectric film 260 may increase, and the reliability of the IC device 200 may improve.

FIGS. 5A to 5J are cross-sectional views of a process sequence of a method of manufacturing an IC device, according to some example embodiments. In FIGS. 5A to 5J, the same reference numerals are used to denote the same elements as in FIGS. 3 and 4A to 4C, and detailed descriptions thereof are omitted.

Referring to FIG. 5A, a lower structure 220 and a conductive region 224 may be formed on a substrate 210 in which an active region AC is defined by the device isolation film 212. The conductive region 224 may pass through the lower structure 220 and be connected to the active region AC. Thereafter, an insulating film 226 may be formed to cover the lower structure 220 and the conductive region 224.

The insulating film 226 may be used as an etch stop layer during a subsequent process. The insulating film 226 may include an insulating material having an etch selectivity with respect to the lower structure 220. In some example embodiments, the insulating film 226 may include a silicon nitride (SiN) film, a silicon carbon nitride (SiCN) film, a silicon boron nitride (SiBN) film, or a combination thereof.

Referring to FIG. 5B, a mold structure MST may be formed on the insulating film 226.

The mold structure MST may include a plurality of mold films and a plurality of support films. For example, the mold structure MST may include a first mold film 232, a lower insulating support film 242, a second mold film 234, and an upper insulating support film 244, which are sequentially stacked on the insulating film 226. Each of the first mold film 232 and the second mold film 234 may include a material, which has a relatively high etch rate with respect to an etchant including ammonium fluoride (NH₄F), hydrofluoric acid (HF), and water and may be removed by a lift-off process using the etchant. In some example embodiments, each of the first mold film 232 and the second mold film 234 may include an oxide film, a nitride film, or a combination thereof. For example, the first mold film 232 may include a boro phospho silicate glass (BPSG) film. The BPSG film may include at least one of a first portion in which the concentration of a dopant B (boron) varies in a thickness direction of the BPSG film and a second portion in which the concentration of a dopant P (phosphorus) varies in the thickness direction of the BPSG film. The second mold film 234 may include a silicon nitride film or a multilayered insulating film in which a silicon oxide film and a silicon nitride film, each of which has a relatively small thickness, are alternately and repeatedly stacked one-by-one plural times. However, a constituent material of each of the first mold film 232 and the second mold film 234 is not limited to the examples described above and may be variously modified and changed within the scope of the inventive concept. In addition, the order of stacking of films in the mold structure MST is not limited to the example shown in FIG. 5B and may be variously modified and changed within the scope of the inventive concept.

Each of the lower insulating support film 242 and the upper insulating support film 244 may include a silicon nitride (SiN) film, a silicon carbon nitride (SiCN) film, a silicon boron nitride (SiBN) film, or a combination thereof. In some example embodiments, the lower insulating support film 242 and the upper insulating support film 244 may include the same materials as each other. In other example embodiments, the lower insulating support film 242 and the upper insulating support film 244 may include different materials from each other. In some example embodiments, each of the lower insulating support film 242 and the upper insulating support film 244 may include a silicon carbon nitride film. In another example embodiment, the lower insulating support film 242 may include a silicon carbon nitride film, and the upper insulating support film 244 may include a boron-containing silicon nitride film. However, constituent materials of the lower insulating support film 242 and the upper insulating support film 244 are not limited thereto and may be variously modified and changed within the scope of the inventive concepts.

Referring to FIG. 5C, a mask pattern MP may be formed on the mold structure MST in the resultant structure of FIG. 5B. Thereafter, the mold structure MST may be anisotropically etched by using the mask pattern MP as an etch mask and by using the insulating film 226 as an etch stop layer to form a mold structure pattern MSP defining a plurality of holes BH. The mold structure pattern MSP may include a first mold pattern 232P, a lower insulating support pattern 242P, a second mold pattern 234P, and an upper insulating support pattern 244P. The mask pattern MP may include a nitride film, an oxide film, a polysilicon film, a photoresist film, or a combination thereof.

The process of forming the plurality of holes BH may further include wet processing the resultant structure obtained by anisotropically etching the mold structure MST. During the process of wet processing the resultant structure obtained by anisotropically etching the mold structure MST, portions of the insulating film 226 may be etched together, and thus, an insulating pattern 226P having a plurality of openings 226H exposing the plurality of conductive regions 224 may be obtained. An example process for wet processing the resultant structure obtained by anisotropically etching the mold structure MST may be performed using an etchant including a diluted sulfuric acid peroxide (DSP) solution, without being limited thereto.

In the mold structure pattern MSP, a plurality of holes 242H, which are portions of the plurality of holes BH, may be formed in the lower insulating support pattern 242P, and a plurality of holes 244H, which are portions of the plurality of holes BH, may be formed in the upper insulating support pattern 244P.

Referring to FIG. 5D, the mask pattern MP may be removed from the resultant structure of FIG. 5C, and the lower electrode LE2 may be formed to fill the plurality of holes BH.

In some example embodiments, to form the lower electrode LE2, a conductive layer filling the plurality of holes BH and covering a top surface of the upper insulating support pattern 244P may be formed on the resultant structure of FIG. 5D. To form the conductive layer, a chemical vapor deposition (CVD) process, a plasma-enhanced CVD (PECVD) process, a metal organic CVD (MOCVD) process, or an atomic layer deposition (ALD) process may be used. Thereafter, the conductive layer may be partially removed using an etchback process or a chemical mechanical polishing (CMP) process to expose the top surface of the upper insulating support pattern 244P.

Referring to FIG. 5E, portions of the upper insulating support pattern 244P may be removed from the resultant structure of FIG. 5D to form a plurality of upper holes UH. Thereafter, the second mold pattern 234P may be wet removed through the plurality of upper holes UH. Next, portions of the lower insulating support pattern 242P, which are exposed through the plurality of upper holes UH, may be removed to form a plurality of lower holes LH. Thereafter, the first mold pattern 232P may be wet removed through the plurality of lower holes LH to expose a top surface of the insulating pattern 226P. In some example embodiments, the second mold pattern 234P and the first mold pattern 232P may be wet removed using an etchant including ammonium fluoride (NH₄F), hydrofluoric acid (HF), and water, without being limited thereto.

A planar shape of each of the plurality of upper holes UH and the plurality of lower holes LH is not limited to a planar shape shown in FIG. 4A and may be variously selected. After the first mold pattern 232P and the second mold pattern 234P are removed, sidewalls of the plurality of lower electrodes LE2 may be exposed.

Referring to FIG. 5F, a lower interface layer 250 may be selectively formed only on exposed surfaces of the plurality of lower electrodes LE2, from among exposed surfaces of the resultant structure of FIG. 5E.

In some example embodiments, to form the lower interface layer 250, a Ti oxide film may be formed on the exposed surface of the lower electrode LE2 and then doped with a dopant metal that is pentavalent. In some example embodiments, the dopant metal may include Nb, Ta, Sb, V, and/or a combination thereof. In other example embodiments, when the lower electrode LE2 includes TiN, the Ti oxide film may be formed on the exposed surface of the lower electrode LE2 by oxidizing the exposed surface of the lower electrode LE2.

Referring to FIG. 5G, in the resultant structure of FIG. 5F, a dielectric film 260 may be formed to cover exposed surfaces of the lower interface layer 250, exposed surfaces of each of the lower insulating support pattern 242P and the upper insulating support pattern 244P, and exposed surfaces of the insulating pattern 226P.

The dielectric film 260 may be formed using an ALD process. The dielectric film 260 may include HfO₂, ZrO₂, Al₂O₃, La₂O₃, Ta₂O₃, Nb₂O₅, CeO₂, TiO₂, GeO₂, and/or a combination thereof, without being limited thereto.

Referring to FIG. 5H, a transition metal-Al complex oxide layer 272 conformally covering the dielectric film 260 may be formed on the resultant structure of FIG. 5G.

In some example embodiments, to form the transition metal-Al complex oxide layer 272, a transition metal oxide film may be formed on the exposed surface of the dielectric film 260 and then doped with aluminum (Al). In other example embodiments, when the exposed surface of the dielectric film 260 includes a transition metal oxide film (e.g., a HfO₂ film or a ZrO₂ film), to form the transition metal-Al complex oxide layer 272, a process of forming a transition metal oxide film on the exposed surface of the dielectric film 260 may be omitted, and the exposed surface of the dielectric film 260 may be doped with Al.

Referring to FIG. 5I, an upper interface layer 274 conformally covering the transition metal-Al complex oxide layer 272 may be formed in the resultant structure of FIG. 5H. The transition metal-Al complex oxide layer 272 and the upper interface layer 274 may constitute a multilayered interface structure 270.

In some example embodiments, the upper interface layer 274 may be formed by using an ALD process or a CVD process. For example, to form the upper interface layer 274, a metal oxide film including an oxide of at least one metal selected from Ti, Nb, Ta, Sn, and/or Mo or a metal oxynitride film including an oxynitride of at least one metal selected from Ti, Nb, Ta, Sn, and/or Mo may be formed by using an ALD process or a CVD process.

In other example embodiments, to form the upper interface layer 274, a metal nitride film including a nitride of at least one metal selected from Ti, Nb, Ta, Sn, and/or Mo may be formed on the transition metal-Al complex oxide layer 272, and a portion of the metal nitride film may be then oxidized from an exposed surface of the metal nitride film. In the upper interface layer 274 obtained as the result, a content ratio of nitrogen atoms may increase toward the transition metal-Al complex oxide layer 272, and a content ratio of oxygen atoms may increase toward an exposed surface of the upper interface layer 274. For example, to form the upper interface layer 274, a Mo nitride film conformally covering the transition metal-Al complex oxide layer 272 may be formed, and a portion of the Mo nitride film may be oxidized from an exposed surface of the Mo nitride film to form a Mo oxynitride film. In the Mo oxynitride film obtained using the above-described method, a content ratio of nitrogen atoms may increase toward the transition metal-Al complex oxide layer 272, and a content ratio of oxygen atoms may increase toward the exposed surface of the Mo oxynitride film.

In still other example embodiments, to form the upper interface layer 274, a metal nitride film including a nitride of at least one metal selected from Ti, Nb, Ta, Sn, and/or Mo may be formed, and a metal oxide film including a nitride of at least one metal selected from Ti, Nb, Ta, Sn, and/or Mo may be then formed on the metal nitride film to form a metal oxynitride film. In the metal oxynitride film formed using the above-described method, a content ratio of nitrogen atoms may increase toward the transition metal-Al complex oxide layer 272, and a content ratio of oxygen atoms may increase toward the exposed surface of the metal oxynitride film. For example, to form the upper interface layer 274, after a Mo nitride film is first formed to conformally cover the transition metal-Al complex oxide layer 272, a Mo oxide film conformally covering the Mo nitride film may be formed on the Mo nitride film to form a Mo oxynitride film.

Referring to FIG. 5J, the resultant structure of FIG. 5I, in which the upper interface layer 274 is formed, may be annealed in an inert gas atmosphere 290. The inert gas atmosphere 290 may be an atmosphere including a N₂ gas atmosphere, an Ar gas atmosphere, or a combination thereof. The annealing process may be performed at a temperature of about 400° C. to about 600° C. for about 60 minutes to about 120 minutes, without being limited thereto. A degree of crystallization of the dielectric film 260 may increase due to the annealing process. In some example embodiments, the annealing process described with reference to FIG. 5J may be omitted.

Thereafter, an upper electrode UE2 may be formed on the upper interface layer 274, and thus, the capacitor CP2 shown in FIG. 4B may be formed. In some example embodiments, the upper electrode UE2 may be formed by using a CVD process, an MOCVD process, a physical vapor deposition (PVD) process, or an ALD process.

In the IC device 200 described with reference to FIGS. 3 and 4A to 4C, even when a thickness of the dielectric film 260 is reduced by reducing a space occupied by the capacitor CP2 with the downscaling of the IC device 200, a degree of crystallization of the dielectric film 260 may increase, and thus, the capacitance of the capacitor CP2 including the dielectric film 260 may increase, and the mass productivity and reliability of the IC device 200 may improve.

### Example Embodiment 1

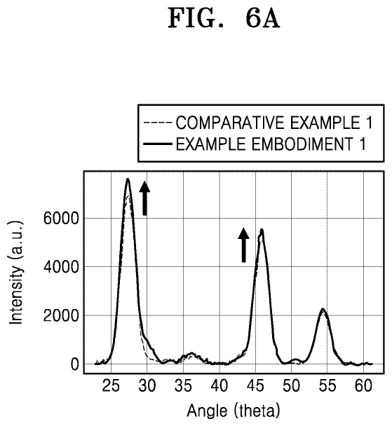

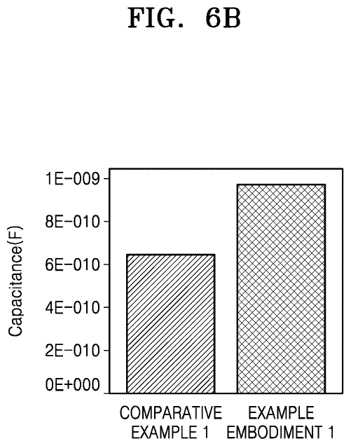

FIG. 6A is a graph of X-ray diffraction (XRD) measurement results showing a comparison of degrees of crystallization of dielectric films included in capacitors of IC devices according to an example embodiment and a comparative example.

In FIG. 6A, Example Embodiment 1 evaluates a degree of crystallization of the dielectric film included in the capacitor formed by using a method of manufacturing an IC device, according to the inventive concept. To prepare a sample of Example Embodiment 1, a lower interface layer including a Nb-doped Ti oxide film was formed to a thickness of 1 Å on a lower electrode including TiN, and a dielectric film having a multilayered structure in which a ZrO₂ film and an Al₂O₃ film were alternately stacked was formed to a thickness of 45 Å on the lower interface layer. A transition metal-Al complex oxide layer including an Al-doped Zr oxide film was formed to a thickness of 10 Å on the dielectric film, and an upper interface layer including a Ti oxide film was formed to a thickness of 40 Å on the transition metal-Al complex oxide layer. The obtained resultant structure was annealed at a temperature of 400° C. for 120 minutes in a N₂ gas atmosphere. Thereafter, an upper electrode including TiN was formed on the obtained resultant structure.

To prepare a sample of Comparative Example 1, substantially the same method as the method of preparing the sample according to Example Embodiment 1 was performed. However, a process of forming a transition metal-Al complex oxide layer was omitted, and a dielectric film was annealed at a temperature of 400° C. for 120 minutes in a N₂ gas atmosphere directly after the dielectric film was formed. Also, an upper interface layer including a Ti oxide film was formed to a thickness of 40 Å on the annealed resultant structure, and an upper electrode including TiN was formed on the upper interface layer without annealing the resultant structure including the upper interface layer.

From the results of FIG. 6A, it can be seen that Example Embodiment 1 having a structure according to the inventive concepts exhibited a higher intensity of an XRD peak than Comparative Example 1. Accordingly, it can be inferred that a degree of crystallization of the structure of Example Embodiment 1 improves compared to a structure of Comparative Example 1.

### Example Embodiment 2

FIG. 6B is a graph of capacitance measurement results of Example Embodiment 1 used for the evaluation of FIG. 6A and a comparative example. From the results of FIG. 6B, it can be seen that a structure of Example Embodiment 1 has significantly improved capacitance compared to a structure of Comparative Example 1.

### Example Embodiment 3

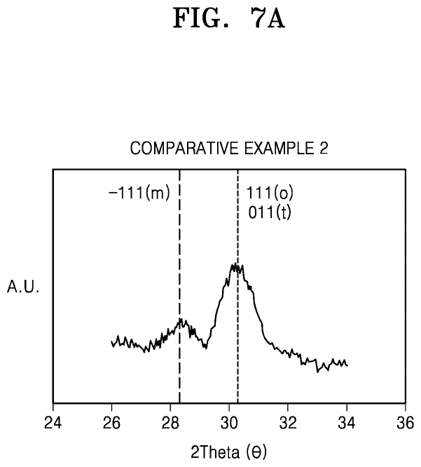

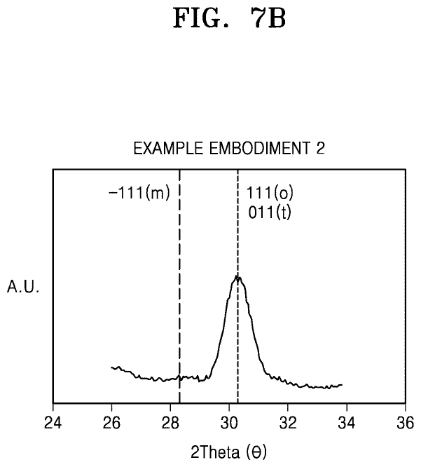

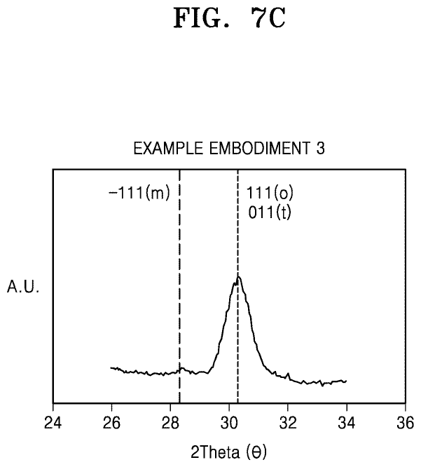

FIGS. 7A, 7B, and 7C are graphs of XRD measurement results showing a comparison of degrees of crystallization of dielectrics films included in capacitors of IC devices according to example embodiments and Comparative Example.

More specifically, FIG. 7A is a graph of evaluating the crystallinity of a dielectric film in a sample of Comparative Example 2. FIG. 7B is a graph of evaluating the crystallinity of a dielectric film in a sample of Example Embodiment 2. FIG. 7C is a graph of evaluating the crystallinity of a dielectric film in a sample of Example Embodiment 3.

To prepare a sample of Comparative Example 2, substantially the same method as the method of preparing the sample according to Comparative Example 1 used for the evaluation of FIG. 6A was performed. However, the process of forming the transition metal-Al complex oxide layer and the process of forming the upper interface layer were omitted. A dielectric film having a multilayered structure in which a HfO₂ film was between a ZrO₂ film and an Al₂O₃ film was formed to a thickness of 45 Å as the dielectric film, and an upper electrode including TiN was formed directly on the dielectric film.

To prepare a sample of Example Embodiment 2, substantially the same method as the method of preparing the sample according to Example Embodiment 1 used for the evaluation of FIG. 6A was performed. However, a dielectric film having a multilayered structure in which a HfO₂ film was between a ZrO₂ film and an Al₂O₃ film was formed to a thickness of 45 Å as the dielectric film, and a Mo nitride film having a thickness of 10 Å was formed as the upper interface layer.

To prepare a sample of Example Embodiment 3, substantially the same method as the method of preparing the sample according to Example Embodiment 1 used for the evaluation of FIG. 6A was performed. However, a dielectric film having a multilayered structure in which a HfO₂ film was between a ZrO₂ film and an Al₂O₃ film was formed to a thickness of 45 Å as the dielectric film, and a Mo oxide film having a thickness of 10 Å was formed as the upper interface layer.

From FIG. 7A, it can be seen that a peak of a monoclinic phase was observed in the case of Comparative Example 2 and was approximately ⅓ of a peak of a tetragonal phase. In contrast, referring to FIGS. 7B and 7C, when the upper interface layer included the Mo nitride film or the Mo oxide film, peaks of monoclinic phases were hardly seen, and there were only peaks of tetragonal phases. From the results of FIGS. 7A, 7B, and 7C, it can be seen that when the upper interface layer included the Mo nitride film or the Mo oxide film, a monoclinic phase of the dielectric film including the HfO₂ film was suppressed, and a tetragonal phase thereof was induced. As a result, the effects of improving a capacitance of the capacitor including the dielectric film while suppressing a leakage current in the capacitor may be expected.

While the inventive concepts have been particularly shown and described with reference to example embodiments thereof, it will be understood that various changes in form and details may be made therein without departing from the spirit and scope of the following claims.

What is claimed is:

1. An integrated circuit device comprising:
a lower electrode;
a dielectric film covering the lower electrode;
an upper electrode covering the dielectric film; and
a multilayered interface structure between the dielectric film and the upper electrode,
wherein the multilayered interface structure includes,
a transition metal-aluminum (Al) complex oxide layer including a transition metal oxide layer in which Al atoms are dispersed, the transition metal-Al complex oxide layer being in contact with the dielectric film, and
an upper interface layer including a metal oxide or a metal oxynitride, the upper interface layer being in contact with the transition metal-Al complex oxide layer.

2. The integrated circuit device of claim 1, wherein
the transition metal-Al complex oxide layer includes a first metal, which is a transition metal, and
the upper interface layer includes a second metal, and
the second metal is a transition metal of a different type from the first metal or a post-transition metal.

3. The integrated circuit device of claim 1, wherein the transition metal-Al complex oxide layer includes zirconium oxide in which Al atoms are dispersed or hafnium oxide in which Al atoms are dispersed.

4. The integrated circuit device of claim 1, wherein the upper interface layer includes an oxide of at least one metal selected from titanium (Ti), niobium (Nb), tantalum (Ta), antimony (Sn), or molybdenum (Mo) or an oxynitride of the at least one metal.

5. The integrated circuit device of claim 1, wherein
the upper interface layer includes the metal oxynitride,
a content ratio of nitrogen atoms in the upper interface layer increases toward the transition metal-Al complex oxide layer, and
a content ratio of oxygen atoms in the upper interface layer increases toward the upper electrode.

6. The integrated circuit device of claim 1, wherein
the upper interface layer includes a Mo oxynitride layer,
a content ratio of nitrogen atoms in the Mo oxynitride layer increases toward the transition metal-Al complex oxide layer, and
a content ratio of oxygen atoms in the Mo oxynitride layer increases toward the upper electrode.

7. The integrated circuit device of claim 1, further comprising:
a lower interface layer between the lower electrode and the dielectric film, the lower interface layer being in contact with the dielectric film,
wherein the lower interface layer includes a Ti oxide film doped with a dopant metal that is pentavalent.

8. The integrated circuit device of claim 7, wherein the dopant metal includes niobium (Nb), tantalum (Ta), antimony (Sb), vanadium (V), or a combination thereof.

9. The integrated circuit device of claim 7, wherein a thickness of the lower interface layer is less than a thickness of each of the transition metal-Al complex oxide layer and the upper interface layer.

10. The integrated circuit device of claim 1, wherein the dielectric film further comprises:
a metal oxide including at least one metal selected from hafnium (Hf), zirconium (Zr), aluminum (Al), niobium (Nb), cerium (Ce), lanthanum (La), tantalum (Ta), or titanium (Ti).

11. An integrated circuit device comprising:
a substrate including an active region;
a conductive region formed on the active region; and
a capacitor formed on the conductive region,
wherein the capacitor includes,
a lower electrode in contact with the conductive region,
a dielectric film covering the lower electrode,
an upper electrode covering the dielectric film, and
a multilayered interface structure between the dielectric film and the upper electrode, and
wherein the multilayered interface structure includes,
a transition metal-aluminum (Al) complex oxide layer including a transition metal oxide layer in which Al atoms are dispersed, the transition metal-Al complex oxide layer being in contact with the dielectric film, and
an upper interface layer including a metal oxide or a metal oxynitride, the upper interface layer being in contact with the transition metal-Al complex oxide layer.

12. The integrated circuit device of claim 11, wherein
the transition metal-Al complex oxide layer includes a first metal, which is a transition metal,
the upper interface layer includes a second metal, wherein the second metal is a transition metal of a different type from the first metal or a post-transition metal, and
the dielectric film includes an oxide of the first metal.

13. The integrated circuit device of claim 11, wherein
the transition metal-Al complex oxide layer includes a first metal selected from zirconium (Zr) and hafnium (Hf),
the upper interface layer includes a second metal selected from titanium (Ti), niobium (Nb), tantalum (Ta), antimony (Sn), and molybdenum (Mo), and
the dielectric film has a crystal structure of a tetragonal phase, an orthorhombic phase, or a monoclinic phase.

14. The integrated circuit device of claim 11, wherein
the upper interface layer includes the metal oxynitride,
a content ratio of nitrogen atoms in the upper interface layer increases toward the transition metal-Al complex oxide layer,
a content ratio of oxygen atoms in the upper interface layer increases toward the upper electrode, and
the content ratio of nitrogen atoms and the content ratio of oxygen atoms in the upper interface layer are each in a range of about 10 at % to about 30 at %.

15. The integrated circuit device of claim 11, wherein
the upper interface layer includes a Mo oxynitride layer,
a content ratio of nitrogen atoms in the Mo oxynitride layer increases toward the transition metal-Al complex oxide layer, and
a content ratio of oxygen atoms in the Mo oxynitride layer increases toward the upper electrode, and
the dielectric film has a crystal structure of a tetragonal phase or an orthorhombic phase.

16. The integrated circuit device of claim 11, further comprising:
a lower interface layer between the lower electrode and the dielectric film, the lower interface layer having one surface in contact with the dielectric film and another surface in contact with the lower electrode,
wherein the lower interface layer includes a Ti oxide film doped with a dopant metal that is pentavalent, and the dopant metal includes Nb, Ta, Sb, V, or a combination thereof, and
the lower electrode includes a titanium nitride (TiN) film.

17. An integrated circuit device comprising:
a substrate including an active region;
a plurality of conductive regions formed on the active region;
an insulating pattern extending in a lateral direction on the plurality of conductive regions, the insulating pattern having a plurality of openings vertically overlapping the plurality of conductive regions;
a plurality of lower electrodes passing through the insulating pattern via the plurality of openings and extending long in a vertical direction, the plurality of lower electrodes being connected to the plurality of conductive regions;
an insulating support pattern extending in the lateral direction spaced apart from the insulating pattern in the vertical direction, the insulating support pattern being in contact with a partial region of each of the plurality of lower electrodes to support the plurality of lower electrodes;
a dielectric film covering the plurality of lower electrodes, the insulating pattern, and the insulating support pattern;
an upper electrode covering the dielectric film;
a lower interface layer between the plurality of lower electrodes and the dielectric film, the lower interface layer being in contact with the dielectric film; and
a multilayered interface structure between the dielectric film and the upper electrode,
wherein the lower interface layer includes a Ti oxide film doped with a dopant metal that is pentavalent,
wherein the multilayered interface structure includes,
a transition metal-aluminum (Al) complex oxide layer including a transition metal oxide layer in which Al atoms are dispersed, the transition metal-Al complex oxide layer being in contact with the dielectric film, and
an upper interface layer comprising a metal oxide or a metal oxynitride, the upper interface layer being in contact with the transition metal-Al complex oxide layer.

18. The integrated circuit device of claim 17, wherein
the transition metal-Al complex oxide layer includes a first metal selected from zirconium (Zr) and hafnium (Hf),
the upper interface layer comprises a second metal selected from at least one of titanium (Ti), niobium (Nb), tantalum (Ta), antimony (Sn), or molybdenum (Mo), and
the dielectric film has a crystal structure of a tetragonal phase, an orthorhombic phase, or a monoclinic phase.

19. The integrated circuit device of claim 17, wherein
the upper interface layer includes a Mo oxynitride layer,
a content ratio of nitrogen atoms in the Mo oxynitride layer increases toward the transition metal-Al complex oxide layer,
a content ratio of oxygen atoms in the Mo oxynitride layer increases toward the upper electrode, and
the dielectric film has a crystal structure of a tetragonal phase or an orthorhombic phase.

20. The integrated circuit device of claim 17, wherein
the transition metal-Al complex oxide layer includes a first metal that is a transition metal,
the upper interface layer includes a second metal, wherein the second metal is a transition metal of a different type from the first metal or a post-transition metal, and
the dielectric film includes an oxide of the first metal.
